(19) United States
(12) Patent Application Publication
(10) Pub. No.: US 2015/0155410 A1
(43) Pub. Date: Jun. 4, 2015

(54) HIGH EFFICIENCY DOUBLE-GLASS SOLAR MODULES

(71) Applicant: Changzhou Almaden Co., Ltd., Changzhou (CN)

(72) Inventors: Jinxi Lin, Changzhou (CN); Jinhan Lin, Changzhou (CN); Yuting Lin, Wufeng Township (TW); Chun Liang Lin, New Taipei City (TW)

(21) Appl. No.: 14/560,066

(22) Filed: Dec. 4, 2014

(30) Foreign Application Priority Data
Dec. 4, 2013 (CN) 201310647331.X

(51) Int. Cl. H01L 31/048; H01L 31/0216

(52) U.S. Cl. CPC H01L 31/0488; H01L 31/02168

(57) ABSTRACT

The subject invention discloses a solar cell module with a first glass layer and a first encapsulated layer located above the first glass layer. Between the first glass layer and the first encapsulated layer there is a light diffuse-reflection coating. The solar cell module also has a solar cell located above the first encapsulated layer, a second encapsulated layer located above the solar cell, a second glass layer located above the second encapsulated layer, and an anti-reflection coating located above the second glass layer.

### CROSS-REFERENCE TO RELATED APPLICATIONS

This application claims the benefit of China (P.R.C.) Patent Application No. 201310647331.X, which was filed on Dec. 4, 2013, and is incorporated by reference in its entirety herein.

### BACKGROUND OF THE INVENTION

1. Field of the Invention

The present invention is directed to a highly efficient solar cell module, and particularly to a highly efficient double-glass solar cell module.

2. Description of the Related Art

Solar energy is the most prevalently used source of environmentally friendly energy. Generally, solar energy is converted into electric energy by utilizing the photovoltaic effect of solar cells. Solar cells are environmentally friendly and energy efficient, and have been gaining ground in daily applications.

A solar cell module is generally formed by combining a multilayered structure of glass, ethylene vinyl acetate (EVA), solar cell panels (solar cell panels with a size of 5 inches or 6 inches generally put together to form a larger area) and a polymer back sheet, in addition to peripheral components such as outer frame made of aluminum, galvanized steel sheet, wood and synthetic materials (such as polyethylene (PE), polypropylene (PP) and ethylene-propylene rubber), a junction box, lead wires, and a battery. Under sunlight irradiation, the solar cell module outputs a certain working voltage and working current through photovoltaic effect.

It is available in the market that a glass layer is used to replace the polymer back sheet of the solar cell module. Such module is called a double-glass solar cell module. In comparison with a typical solar module, a double-glass solar module not only has safety advantages such as fire resistance, voltage endurance and impact resistance, but also may improve light transmission and achieve decorative effects. Thus, it can be used as a glass component for architecture. Its size and appearance can be custom-made according to the demand of architects or designers and have diversity and artistry.

Since the modern architecture begins to promote building-integrated photovoltaics (BIPV), the application of the double-glass solar cell module is more widespread. BIPV refers to photovoltaic materials that are used to replace conventional building materials, so the building itself can be a large source of energy and additional solar panels are unnecessary to be installed thereto. Because it is considered together at the design stage, the ratio of solar generating efficiency to the cost is optimized. In BIPV technology, double-glass solar cell modules are especially used.

A solar cell module with a large area is formed by putting together solar cells having a small area. To avoid overlap of solar cells (that is, one solar cell on top of another) in the lamination process of the preparation of the solar cell module, gaps are usually kept between solar ells. The gaps are about 2 to 5% of the total area of the solar cell module. However, overly large gaps result in a portion of light passing through the solar cell module not passing through the solar cells. Thus, the overall efficiency of the solar cell module is lower than that of the individual solar cell and the solar cell module generates less power than expected. For a conventional solar cell module, the light passing through the gaps of the solar cell module can be reflected, for example by a white reflective back sheet, back to the solar cells for absorption. However, for a double-glass solar cell module, since the back side is transparent glass, the light passing through the gaps cannot be reflected back to the cells. Thus, it is more likely to cause a decrease in power.

To solve the above-mentioned technical problem, the subject application provides a highly efficient double-glass solar cell module.

### SUMMARY OF THE INVENTION

One object of the subject invention is to provide a solar cell module, comprising:

a first glass layer;

a first encapsulated layer located above the first glass layer, wherein between the first glass layer and the first encapsulated layer there is a light diffuse-reflection coating;

a solar cell located above the first encapsulated layer;

a second encapsulated layer located above the solar cell;

a second glass layer located above the second encapsulated layer; and

an anti-reflection coating located above the second glass layer.

### BRIEF DESCRIPTION OF THE DRAWINGS

FIG. 1 shows a cross-section view of a solar cell module of the concrete embodiment of the subject invention.

### PREFERRED EMBODIMENTS OF THE PRESENT INVENTION

In this context, unless otherwise limited, a singular term (such as “a”) also includes the plural form thereof. In this context, all embodiments and exemplary terms (for example, “such as”) only aim at making the present invention more clearly understood, but are not intended to limit the scope of the present invention; terms in this specification should not be construed as implying that any component not claimed may form a necessary component for implementing the present invention.

The subject invention provides a solar cell module, comprising: a first glass layer; a first encapsulated layer located above the first glass layer, wherein between the first glass layer and the first encapsulated layer there is a light diffuse-reflection coating; a solar cell located above the first encapsulated layer; a second encapsulated layer located above the solar cell; a second glass layer located above the second encapsulated layer; and an anti-reflection coating located above the second glass layer.

The following paragraphs are directed to further explanations for each part of the solar cell module and technical features of the subject invention.

The first glass layer or the second glass layer of the present invention preferably has a thickness from about 0.5 mm to about 3 mm, The glass used in the glass layer of the subject invention is preferably tempered glass. The tempered glass can be a novel type of physical tempered glass, which may be made through treatment procedures such as aerodynamic heating and cooling. Specifically, this physical tempered glass may be made by performing heating in an aerodynamic-heating tempering furnace (such as a flatbed tempering furnace produced by LiSEC Corporation) at a temperature ranging from about 600° C. to about 750° C., preferably from about 630° C. to about 700° C., and then performing rapid cooling through, for example, an air nozzle. In this context, the term “aerodynamic heating” refers to a process of transferring heat to an object through high-temperature gas generated when the object and air or other gases move at a high relative velocity or a process of transferring heat to an object through gas flotation principle to replace conventional direct-contact manner when the object passes through the heating furnace or tempering furnace. When the tempered glass is heated in the aerodynamic heating manner, the glass and the tempering furnace do not directly contact, so the glass is not deformed, and is suitable for thin glass. For a more detailed physical tempered glass preparation method, reference may be made to the content of Chinese Patent Application No. 201110198526.1 (corresponding to U.S. patent application Ser. No. 13/541,995). The tempered glass suitable for the present invention is transparent ultrathin tempered glass with a thickness preferably of 0.5 mm to 2.5 mm. The physical tempered glass suitable for the present invention should have a compressive strength of about 120 MPa to about 300 MPa, preferably about 150 MPa to about 250 MPa, a bending strength of about 120 MPa to about 300 MPa, preferably about 150 MPa to about 250 MPa, and a tensile strength of about 90 MPa to about 180 MPa, preferably about 100 MPa to about 150 MPa.

In the prior art, an embossing glass may be used on the light incident side of the solar cell module. The embossing glass is transparent decorative flat glass with a concave-convex pattern on a single side or double sides which is prepared by special pressing techniques. The embossing glass has a special pattern, such as pyramid, honeycomb, rhombus and so on, on the surface of the glass which is usually pressed by using a tailor-made engraved roller. A special embossing design may reduce direct reflection of light from the glass, increase internal reflection, facilitate absorption of light energy, substantially increase the transmittance of sunlight and enhance the efficiency of power generation. It has outstanding advantages in terms of high sun energy transmittance, low reflection rate, high mechanical strength, high flatness and so on. In the present invention, the second glass layer is preferably tempered embossing glass, wherein the thickness of the embossing of the tempered embossing glass is of about 5 μm to 150 μm and the embossing surface of the tempered embossing glass faces the solar cell. The above-mentioned ranges may include any value in the ranges or any subrange within the ranges. Taking a thickness from about 40 nm to about 70 nm for example, the range of the thickness can include from about 48 nm to about 57 nm, or from about 53 nm to about 65 nm. Other ranges in the subject application are defined in the same manner, i.e., they may include any value in the ranges or any subrange within the ranges.

The encapsulated layer used in the solar cell module of the present invention is mainly to fix the optoelectronic elements of the solar cell and to provide physical protection for them, for example, impact and moisture resistance. The encapsulated layer in the solar cell module of the present invention can be made of any conventional material, including ethylene vinyl acetate (EVA), polyvinyl butyral (PVB), thin film ionic polymers, such as Dupont PV5400, and silicone resin, of which ethylene vinyl acetate is presently the most extensively used encapsulated layer material. EVA is a thermosetting resin that offers high transmittance, thermo resistance, thermal insulation (low temperature resistance), moisture resistance, and weather resistance after being cured. In addition, it adheres well to metals, glass and plastics, and has certain elasticity, impact resistance and thermo conductivity. Thus, EVA is an ideal material for the solar cell encapsulated layer.

In the present invention, the solar cell is located between the first encapsulated layer and the second encapsulated layer. Its type is not particularly limited. A monocrystalline silicon, polycrystalline silicon, amorphous silicon or thin-film solar cell or the like can be used.

In the present invention, between the first glass layer and the first encapsulated layer there is a light diffuse-reflection coating, wherein the light diffuse-reflection coating is a white coating with a thickness from 10 to 50 μm, preferably from 25 to 40 μm. Its surface roughness (Ra) is of 0.05 to 20 μm, preferably 0.5 to 10 μm. The material of the light diffuse-reflection coating may include SiOx, TiO₂, ZrOx, AlOx, ZnOx or TaOx. The purpose of the light diffuse-reflection coating is to enable the light passing through the gaps between the solar cells in a solar cell module to be diffusively reflected. According to the subject invention, the reflectivity of the total reflection of the light diffuse-reflection coating is equal to or more than 80% for the visible light region. For the reflected light, the ratio of the mirror reflection is equal to or less than 40%, based on the total reflection.

In one embodiment of the present invention, the second glass layer is tempered embossing glass. The embossing surface is near to the surface of the second encapsulated layer. Another surface has an anti-reflection coating.

In the present invention, the optical refractive index of the second encapsulated layer is preferably more than 1.5. The object is to increase waveguide effects, increase the probability that the light reflected from the light diffuse-reflection coating is reflected back to the solar cells through the embossing surface of the second glass layer, covert the solar energy to electric energy, thereby improve the overall efficiency of the solar cell module. For example, the second encapsulated layer having high refractive index may comprise EVA, PVB, thin film ionic polymers or silicone resin to which the additive materials are added. The additive materials can be high refractive index particles of TiO₂ or ZrO₂ with a size of about 10 nm. In addition, phenyl organosilicon materials can also be the encapsulated material having high refractive index.

In the present invention, the material of the anti-reflection coating may include SiOx or AlOx. The optical refractive index of the anti-reflection coating is of 1.2 to 1.4, preferably of 1.25 to 1.3. The thickness is of about 80 to 120 nm, preferably of about 90 to 110 nm. The object of the anti-reflection coating is to prevent the reflection of the incident light and may increase about 1 to 3% of the transmittance of the incident light passing through the second glass layer.

In the present invention, a method known by a person of ordinary skill in the art can be used for forming the light diffuse-reflection coating or anti-reflection coating on glass. For example, a dry coating method or wet coating method. The dry coating method can be, for example, chemical vapor deposition or physical vapor deposition. The wet coating method can be, for example, electroplating, knife coating, roller coating, flow coating, curtain coating, spin coating, spray coating, bar coating, slot die coating, gravure coating, slide coating or other conventional methods, or the combination of the above.

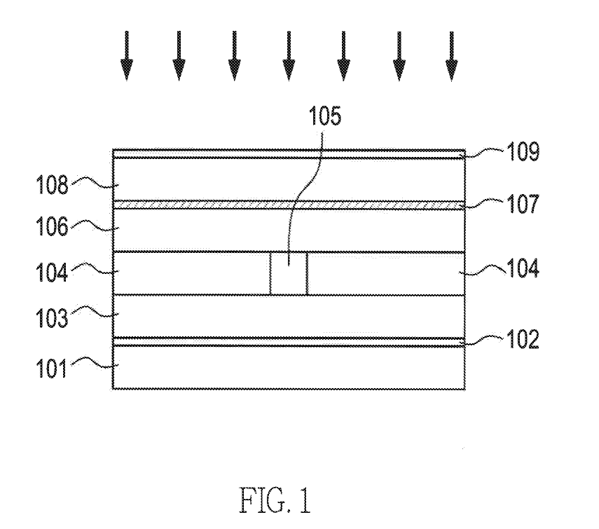

As shown in FIG. 1, in the embodiment of the present invention, the arrow symbol represents the direction of light incidence, 101 is a first glass layer, 102 is a light diffuse-reflection coating, 103 is a first encapsulated layer, 104 is a solar cell, 105 is a gap between the solar cells, 106 is a second encapsulated layer, 107 is an embossing surface of a second glass layer, 108 is the second glass layer, and 109 is an anti-reflection coating. If the incident light passes through the gap, it can be reflected by the light diffuse-reflection coating above the first glass layer. The light passes the first encapsulated layer, the gap and the second encapsulated layer and is reflected by the embossing surface of the second glass layer to the solar cell so that the solar cell absorbs the light and produces electricity.

In one embodiment of the present invention, the first or the second encapsulated layer is made of ethylene vinyl acetate or polyvinyl butyral.

In one embodiment of the present invention, the glass layer is tempered glass having a compressive strength of about 120 MPa to about 300 MPa, preferably about 150 MPa to about 250 MPa, a bending strength of about 120 MPa to about 300 MPa, preferably about 150 MPa to about 250 MPa, and a tensile strength of about 90 MPa to about 180 MPa, preferably about 100 MPa to about 150 MPa.

In one embodiment of the present invention, each of the first and second encapsulated layers has a thickness of about 0.3 mm to 0.9 mm, preferably about 0.4 mm to 0.8 mm.

One or more embodiments of the subject invention are illustrated in the following descriptions. Other features, objects and advantages of the subject invention will be easily understood from these descriptions and the claims.

### EXAMPLE

In this example, 2 mm tempered glass is taken. A light diffuse-reflection coating with a thickness of about 32 μm made of TiO₂ is formed on the tempered glass by wet coating. An encapsulated layer made of EVA was formed on the light diffuse-reflection coating by using a lamination process. Sixty solar cells were attached to the encapsulated layer by the lamination, wherein the space between the solar cells was about 2 mm. Another encapsulated layer made of EVA was formed on the solar cells by the lamination. Then, 2 mm tempered embossing glass was formed on the encapsulated layer by the lamination, wherein the embossing surface of the tempered embossing glass is contacted with the encapsulated layer. Then, an anti-reflection coating made of SiOx with a thickness of about 110 nm is formed on the tempered embossing glass by wet coating, wherein the anti-reflection coating has an optical refraction index of about 1.3. Finally, the solar cell module of the present invention was prepared. The power of the solar cell module of the present invention was measured as 247 W.

Thus, in comparison with the solar cell module without a light diffuse-reflection coating and without an anti-reflection coating, the solar cell module obtained from the present invention was found to generate 1.75% more power.

Although illustrative embodiments have been described in reference to the subject invention, it should be understood that features which can be easily modified or adjusted by a person of ordinary skill in the art would fall into the scope of the specification of the subject application and the claims attached hereto.

What is claimed is:

1. A solar cell module, the module comprising:
a first glass layer;
a first encapsulated layer located above the first glass layer, wherein between the first glass layer and the first encapsulated layer there is a light diffuse-reflection coating;
a solar cell located above the first encapsulated layer;
a second encapsulated layer located above the solar cell;
a second glass layer located above the second encapsulated layer; and
an anti-reflection coating located above the second glass layer.

2. The solar cell module according to claim 1, herein the first glass layer, the second glass layer or both are tempered glass.

3. The solar cell module according to claim 2, wherein the second glass layer is tempered embossing glass.

4. The solar cell module according to claim 3, wherein the embossing on the tempered embossing glass has a thickness from about 5 to 150 μm.

5. The solar cell module according to claim 1, wherein the first glass layer or the second glass layer has a thickness from about 0.5 mm to about 3 mm.

6. The solar cell module according to claim 2, wherein he first glass layer or the second glass layer has a thickness from about 0.5 mm to about 3 mm.

7. The solar cell module according to claim 1, wherein the first encapsulated layer or the second encapsulated layer comprises ethylene vinyl acetate, polyvinyl butyral, a thin-film ionic polymer, or silicone resin.

8. The solar cell module according to claim 2, wherein the first encapsulated layer or the second encapsulated layer comprises ethylene vinyl acetate, polyvinyl butyral, a thin-film ionic polymer, or silicone resin.

9. The solar cell module according to claim 1, wherein the second encapsulated layer has an optical refraction index more than 1.5.

10. The solar cell module according to claim 2, wherein the second encapsulated layer has an optical refraction index more than 1.5.

11. The solar cell module according to claim 1, wherein the light diffuse-reflection coating has a thickness from 10 μm to 50 μm.

12. The solar cell module according to claim 2, wherein the light diffuse-reflection coating has a thickness from 10 μm to 50 μm.

13. The solar cell module according to claim 1, wherein the surface roughness (Ra) of the light diffuse-reflection coating is of 0.5 μm to 10 μm.

14. The solar cell module according to claim 2, wherein the surface roughness (Ra) of the light diffuse-reflection coating is of 0.5 μm to 10 μm.

15. The solar cell module according to claim 1, wherein the material of the light diffuse-reflection coating comprises SiOx, TiO₂, ZrOx, AlOx, ZnOx or TaOx.

16. The solar cell module according to claim 2, wherein the material of the light diffuse-reflection coating comprises SiOx, TiO₂, ZrOx, AlOx, ZnOx or TaOx.

17. The solar cell module according to claim 1, wherein the material of the anti-reflection coating comprises SiOx or AlOx.

18. The solar cell module according to claim 2, wherein the material of the anti-reflection coating comprises SiOx or AlOx.
